(19) United States
(12) Patent Application Publication
(10) Pub. No.: US 2006/0216545 A1
(43) Pub. Date: Sep. 28, 2006

(54) Electroluminescent polymer having 9-fluoren-2-yl-2,7-fluorenyl unit and electroluminescent device using same

(75) Inventors: Hong You, Daejeon (KR); Dong Cheol Shin, Daejeon (KR); Sang Soo Lee, Daejeon (KR); Jae Kyu Jin, Daejeon (KR)

Correspondence Address: DARBY & DARBY P.C., P. O. BOX 5257, NEW YORK, NY, 10150-5257, US

(73) Assignee: SK CORPORATION, Seoul (KR)

(21) Appl. No.: 11/377,474

(22) Filed: Mar. 15, 2006

(30) Foreign Application Priority Data
Mar. 25, 2005 (KR) 10-2005-0024889

(51) Int. Cl. H01L 51/54; H05B 33/12; C09K 11/06; C08G 61/00

(52) U.S. Cl. 428/690; 428/917; 313/504; 313/506; 257/40; 257/E51.032; 257/E51.036; 528/394; 528/397

(57) ABSTRACT

A highly functional electroluminescent polymer which has a 9-fluoren-2-yl-2,7-fluorenyl unit and in which substituted fluorenyl groups are introduced to a 9-position of fluorene, and an electroluminescent device using the same. The electroluminescent polymer includes host monomers required to produce a highly efficient host material for blue, green, and red colors, and has high functionality, such as high solubility, thermal stability, and quantum efficiency.

### INCORPORATION BY REFERENCE

The present application claims priority under 35 U.S.C. §119 to Korean Patent Application No. 10-2005-0024889 filed on Mar. 25, 2005. The content of the application is incorporated herein by reference in its entirety.

### BACKGROUND OF THE INVENTION

1. Field of the Invention

The present invention relates to an electroluminescent polymer having a 9-fluoren-2-yl-2,7-fluorenyl unit, and an electroluminescent device using the same. More particularly, the present invention pertains to an electroluminescent polymer having a 9-fluoren-2-yl-2,7-fluorenyl unit which has excellent thermal stability, photostability, solubility, moldability of a film, and quantum efficiency, and an electroluminescent device using the same.

2. Description of the Related Art

Recently, our advance into a highly information-oriented society has been accelerated in accordance with the rapid growth in optical communications and multimedia fields. Hence, an optoelectronic device using conversion of a photon into an electron or conversion of an electron into a photon has been considered a core of the current information electronic industry.

Semiconductor optoelectronic devices may be roughly classified into electroluminescent devices, non-emissive devices, and combinations thereof.

Most displays are non-emissive types, but an electroluminescent display has a rapid response speed and is an emissive type, thus it has various advantages, such as making back-lighting unnecessary and having excellent brightness. Accordingly, it is being touted as a next-generation display.

Electroluminescent devices are classified into inorganic electroluminescent devices and organic electroluminescent devices according to the material used in forming a light-emitting layer.

Organic electroluminescence (EL) is a phenomenon in which an electron and a hole are transported from a cathode and an anode and then combined with each other in an organic material if an electrical field is applied to the organic material, and energy generated at this time is emitted in a light form. The electroluminescence of the organic material was reported by Pope et al. in 1963, and has been frequently studied since an emissive device, which had been called allumina-quinone, had been produced using a pigment having a π-conjugated structure, and had a multilayered structure having quantum efficiency of 1% and brightness of 1000 cd/m2 at 10 V or less, had been reported by Tang et al. of Eastmann Kodak Corp. in 1987. It is advantageous in that, since a synthesis path is simple, it is easy to synthesize various types of materials and it is possible to conduct color tuning. However, processability and thermal stability are poor, and Joule heat is generated in the light-emitting layer when voltage is applied thereto, thus molecules are rearranged and the device is damaged, causing reduction in light-emitting efficiency or in lifespan of the device. Therefore, in order to avoid the above disadvantages, it has been replaced with an organic electroluminescent device having a polymer structure.

With respect to this, FIG. 1 illustrates a structure of a conventional electroluminescent device which includes a substrate/an anode/a hole transport layer/a light-emitting layer/an electron transport layer/and a cathode.

Referring to FIG. 1, an anode 12 is formed on an upper side of a substrate 11. A hole transport layer 13, a light-emitting layer 14, an electron transport layer 15, and a cathode 16 are sequentially formed on an upper side of the anode 12. In connection with this, the hole transport layer 13, the light-emitting layer 14, and the electron transport layer 15 are organic thin films made of organic compounds. An actuation mechanism of the electroluminescent device is as follows.

If voltage is applied between the anode 12 and the cathode 16, a hole which is injected from the anode 12 is moved through the hole transport layer 13 to the light-emitting layer 14. Meanwhile, an electron is injected from the cathode 16 through the electron transport layer 15 into the light-emitting layer 14, and carriers are recombined with each other in the light-emitting layer 14 to form excitons. The excitons are changed from an excited state to a base state, thus fluorescent molecules of the light-emitting layer emit light, thereby forming an image.

The electroluminescent device which is actuated based on the above-mentioned mechanism is classified into a high-molecular organic electroluminescent device and a low-molecular organic electroluminescent device according to the molecular weight of the material used in forming the organic film.

Generally, in the case of using a low-molecular material to form the organic film, since the low-molecular material is easily purified, it is possible to remove almost all impurities, thus light-emitting properties are excellent. However, it is problematic in that it is impossible to conduct inkjet printing or spin coating, and deterioration or recrystallization occurs due to actuation heat generated during actuation of the device because heat resistance is poor.

On the other hand, in the case of using a high molecular material to form the organic film, an energy level is divided into a conductive band and a pseudo-conductive band due to overlapping of π-electron wave functions of a main chain of the high-molecular material, and a semiconductive property of the high-molecular material is assured and it is possible to realize full color due to band-gap energy corresponding to a difference in energy as described above. Such high molecular material is called a π-conjugated polymer.

Since an electroluminescent device using poly(p-phenylenevinylene: hereinafter, referred to as “PPV”) as a polymer having a conjugated double bond was first announced by a team of professor R. H. Friend of Cambridge University in the U.K. in the year 1990, many studies using an organic polymer have been conducted. In comparison with a low-molecular material, polymers have better heat resistance and allow the possibility of conducting inkjet printing and spin coating, thus it is easy to enlarge a display. As to light-emitting materials, polyphenylenevinylene (PPV) derivatives, polythiophene (Pth) derivatives and the like, which are capable of improving processability and displaying various colors using a proper substitutent group, are reported. However, when using the polyphenylenevinylene derivatives and polythiophene derivatives, it is possible to obtain highly efficient polymer materials emitting red and green rays among red, green, and blue colors as the three primary colors of light, but it is difficult to obtain a highly efficient polymer material emitting blue light.

Additionally, polyphenylene derivatives, polyfluorene derivatives and the like were reported as polymer materials emitting blue light. Polyphenylene has high oxidation stability and thermal stability but has disadvantages in that light emitting efficiency is low and solubility is poor.

Meanwhile, the piror art as to the above-mentioned polyfluorene derivatives is as follows.

U.S. Pat. No. 6,255,449 discloses a 9-substituted-2,7-dihalofluorene compound suitable as a light emitting material for the light-emitting layer or a carrier transport layer of a light emitting diode, and oligomers and polymers thereof.

U.S. Pat. Nos. 6,309,763 and 6,605,373 disclose an electroluminescent copolymer including a fluorine group and an amine group in a repeating unit. According to the above-mentioned U.S. Pat. No. 6,309,763, the copolymer is useful as a light-emitting layer or a hole transport layer of an electroluminescent device.

WO 02/77060 discloses a conjugated polymer having a spirofluorene unit. According to this patent, the polymer has improved profile characteristics as a light emitting material of electronic parts, such as PLEDs.

As described above, although many studies using the polyfluorene derivatives as the polymer for emitting blue light have been conducted, there remains a need to minimize interaction between an exciton formed in one molecule and an exciton of the adjacent molecule to improve efficiency and to increase lifespan.

### SUMMARY OF THE INVENTION

Accordingly, the present inventors have developed an electroluminescent polymer that has excellent thermal stability, light emitting efficiency, and solubility, minimizes interaction between molecules, includes a fluorene unit substituted with a fluorenyl group having excellent glass transition temperature (Tg) and thermal stability at a 9-position thereof, and is capable of being used as a novel host material for blue, green, and red colors, and an electroluminescent device using the same.

Therefore, an object of the present invention is to provide an electroluminescent polymer which has high thermal stability and oxidation stability and acts as a host material required to highly efficiently realize blue, green, and red colors and in which interaction between molecules is minimized, energy transfer is easy, and a vibronic mode is maximally suppressed to assure excellent light emitting efficiency.

Another object of the present invention is to provide an electroluminescent device produced using the electroluminescent polymer.

In order to accomplish the above object, the present invention provides an electroluminescent polymer expressed by the following Formula 1.

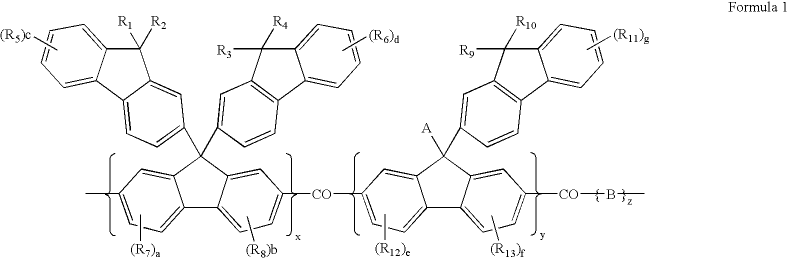

In Formula 1, R1, R2, R3, R4, R9, and R10 are each independently a linear or branched alkyl group of 1-20 carbons; an aryl group which is unsubstituted or substituted with at least one substituent group selected from the group consisting of linear or branched alkyl and alkoxy groups of 1-20 carbons; a linear or branched alkyl group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;

R5, R6, R7, R8, R11, R12, and R13 are each independently a hydrogen; a linear or branched alkyl or alkoxy group of 1-20 carbons; an aryl group which is unsubstituted or substituted with at least one substituent group selected from the group consisting of linear or branched alkyl and alkoxy groups of 1-20 carbons; a linear or branched alkyl or alkoxy group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;

a, b, c, d, e, f, and g are each independently an integer from 1 to 3;

A is an aryl group which is unsubstituted or substituted with at least one substituent group selected from the group consisting of linear or branched alkyl and alkoxy groups of 1-20 carbons; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; or an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si;

B is selected from the group consisting of a substituted or unsubstituted aromatic moiety of 6-60 carbons, a substituted or unsubstituted heteroaromatic moiety of 2-60 carbons, and combinations thereof; and

x is an integer from 1-100,000, y is an integer from 1-100,000, and z is an integer from 0-100,000.

In order to accomplish the other object, the present invention provides an electroluminescent device having at least one layer comprising said electroluminescent polymer between an anode and a cathode,

wherein the layer is an interlayer, a hole transport layer, a light emitting layer, an electron transport layer or a hole blocking layer.

### BRIEF DESCRIPTION OF THE DRAWING

FIG. 1 is a sectional view of a conventional electroluminescent device which includes a substrate/an anode/a hole transport layer/a light-emitting layer/an electron transport layer/a cathode;

FIG. 2 is a sectional view of an electroluminescent device according to an embodiment of the present invention;

FIG. 3 is a sectional view of an electroluminescent device according to another embodiment of the present invention; and

FIG. 4 is a reaction mechanism showing production of monomers used to produce an electroluminescent polymer according to the present invention.

### DETAILED DESCRIPTION OF THE INVENTION

The present invention can be achieved by the following description, referring to the accompanying drawings.

As described above, the present invention provides an electroluminescent polymer including a 9-fluoren-2-yl-2,7-fluorenyl unit, which has high solubility, thermal stability, and quantum efficiency and which is capable of being used as a host material for highly pure blue, green, and red colors, and an electroluminescent device using the same.

The electroluminescent polymer according to the present invention is a material having excellent thermal stability, photostability, solubility, and film moldability, and high quantum efficiency. A fluorenyl group as a large substituent is introduced to a 9-position of fluorene used as a main chain thereof so that the substituent has the same structure as the main chain, thus the main chain and the substituent are randomly arranged, and an excimer between molecules caused by the substituent is maximally suppressed; thereby aggregation and/or formation of an excimer, which are considered the most serious problems in polyfluorenes, are suppressed. Furthermore, energy transfer from the substituent group having a short wavelength to the main chain is possible in a molecule or between molecules.

Additionally, rotation and vibronic modes are supressed due to the large fluorenyl group substituted at the 9-position of the fluorene group used as the main chain to significantly reduce nonradiative decay; thus the organic electroluminescent polymer of the present invention has light emitting properties of excellent chromatic purity and brightness and high efficiency.

The electroluminescent polymer having a 9-fluoren-2-yl-2,7-fluorenyl unit according to the present invention is shown in the following Formula 1.

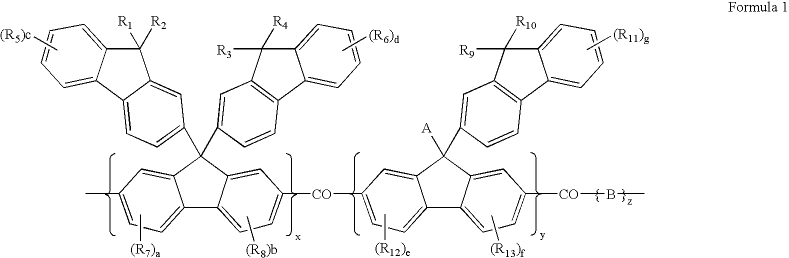

In Formula 1, R1, R2, R3, R4, R9, and R10 are each independently a linear or branched alkyl group of 1-20 carbons; an aryl group which is unsubstituted or substituted with at least one substituent group selected from the group consisting of linear or branched alkyl and alkoxy groups of 1-20 carbons; a linear or branched alkyl group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;

R5, R6, R7, R8, R11, R12, and R13 are each independently a hydrogen; a linear or branched alkyl or alkoxy group of 1-20 carbons; an aryl group which is unsubstituted or substituted with at least one substituent group selected from the group consisting of linear or branched alkyl and alkoxy groups of 1-20 carbons; a linear or branched alkyl or alkoxy group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;

a, b, c, d, e, f, and g are each independently an integer from 1 to 3;

A is an aryl group which is unsubstituted or substituted with at least one substituent group selected from the group consisting of linear or branched alkyl and alkoxy groups of 1-20 carbons; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; or an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si;

B is selected from the group consisting of a substituted or unsubstituted aromatic moiety of 6-60 carbons, a substituted or unsubstituted heteroaromatic moiety of 2-60 carbons, and combinations thereof; and

x is an integer from 1-100,000, y is an integer from 1-100,000, and z is an integer from 0-100,000.

Preferably, a ratio of x+y:z is 50-100:0-50.

The electroluminescent polymer of the present invention shown in Formula 1 is a random copolymer or a syndiotactic copolymer.

Preferably, R1, R2, R3, R4, R9, and R10 are each independently selected from the group consisting of

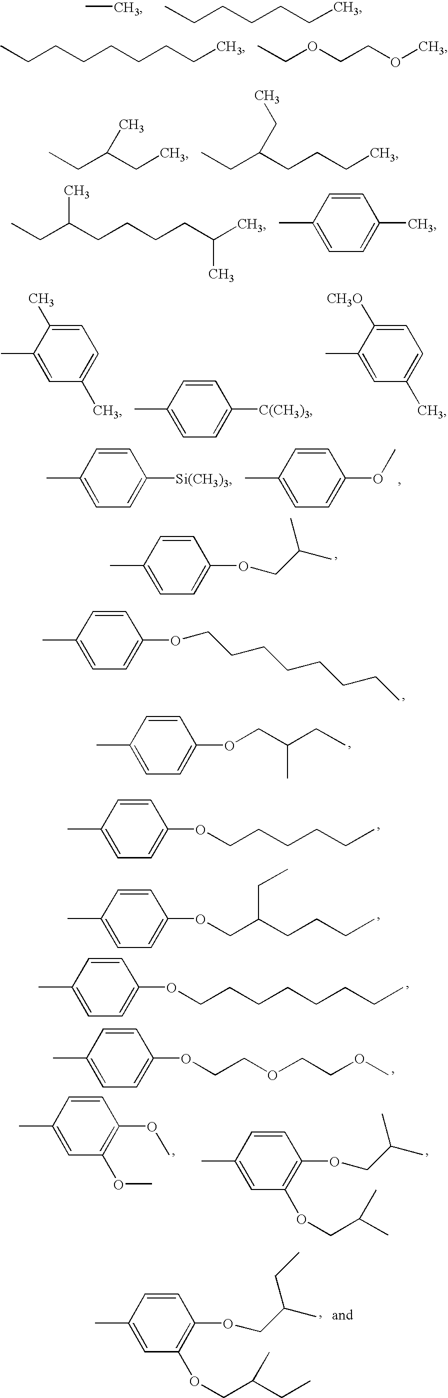

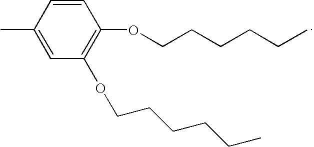

Preferably, R5, R6, and R11 are each independently selected from the group consisting of

hydrogen,

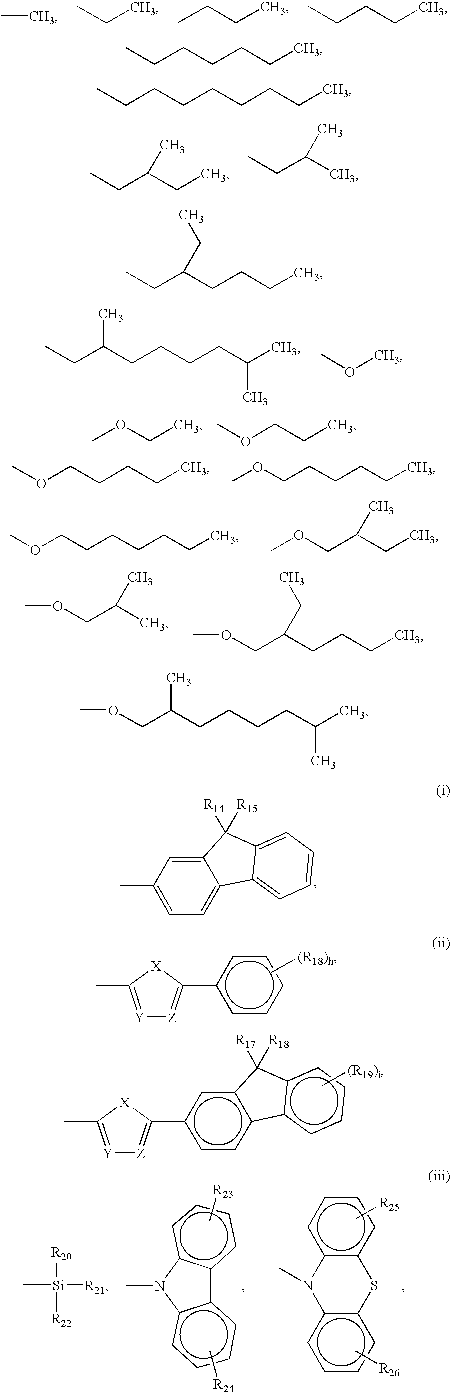

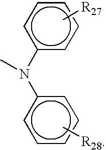

In the above formula (i), R14 and R15 are each independently a linear or branched alkyl group of 1-20 carbons.

Representative examples of these fluorenyl compounds are as follows:

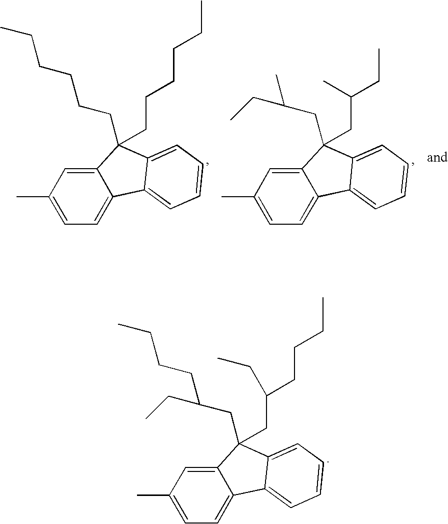

R16 is a hydrogen, a linear or branched alkyl, or an alkoxy or trialkylsilyl group of 1-20 carbons.

R17 and R18 are each independently a linear or branched alkyl group of 1-20 carbons, and R19 is a hydrogen, a linear or branched alkyl, or an alkoxy or trialkylsilyl group of 1-20 carbons.

X is O or S, Y and Z each is N, and h and i are each independently an integer from 1-3.

Representative examples of the above-mentioned aryl compounds having the heterocycles are as follows:

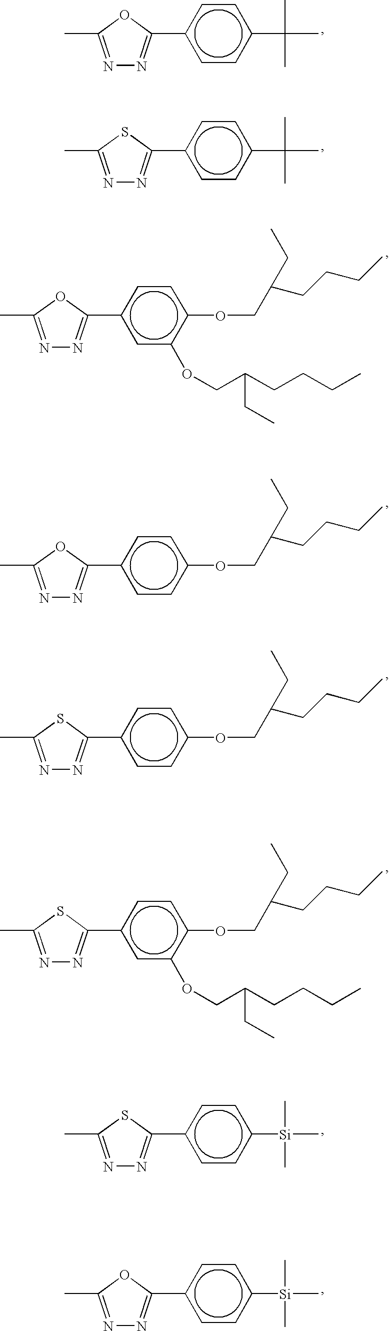

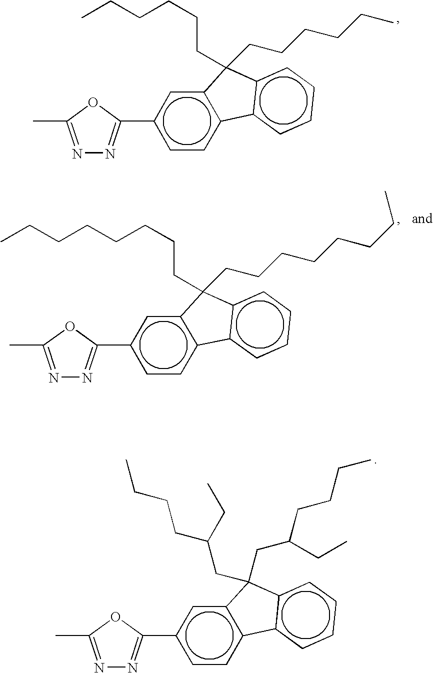

R20, R21, and R22 are each independently a linear or branched alkyl or alkoxy group of 1-20 carbons; or an aryl group which is unsubstituted or substituted with at least one substituent group selected from the group consisting of linear or branched alkyl and alkoxy groups of 1-20 carbons.

R23, R24, R25, R26, R27, and R28 are each independently a hydrogen; a linear or branched alkyl or alkoxy group of 1-20 carbons; or an aryl group which is unsubstituted or substituted with at least one substituent group selected from the group consisting of linear or branched alkyl and alkoxy groups of 1-20 carbons.

Representative examples of these silyl, carbazole, phenothiazine, and arylamine compounds are as follows:

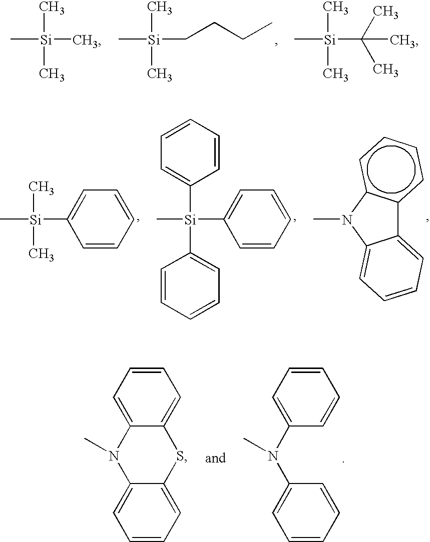

Most preferably, R5, R6, and R11 each is hydrogen.

Preferably, R7, R8, R12, and R13 are each independently selected from the group consisting of

hydrogen,

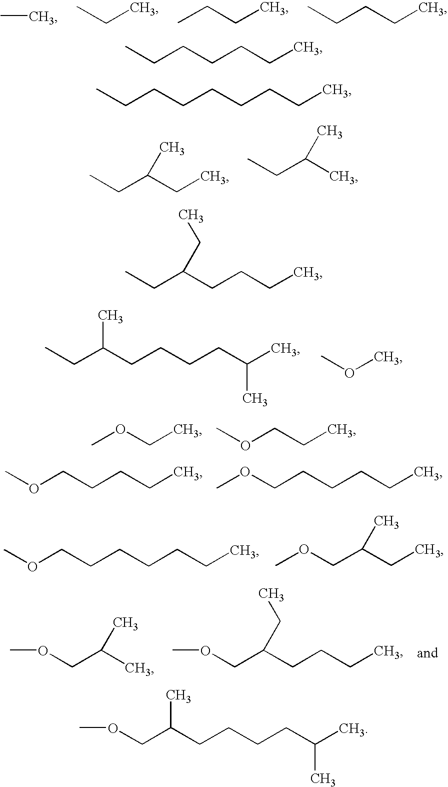

Most preferably, R7, R8, R12, and R13 each is hydrogen.

Preferably, A is shown in the following Formula.

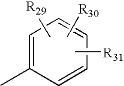

In the above Formula, R29, R30, and R31 are each independently a hydrogen; a linear or branched alkyl or alkoxy group of 1-20 carbons; or a linear or branched alkyl or alkoxy group of 1-20 carbons having at least one hetero-atom selected from the group consisting of F, S, N, O, P and Si.

Representative examples of these compounds are as follows.

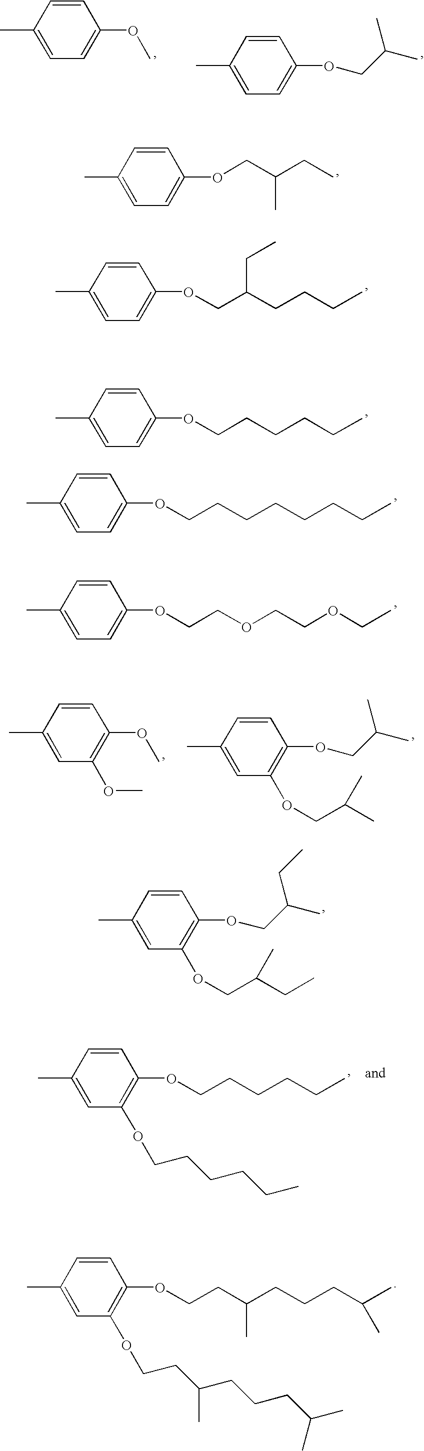

Preferably, B is selected from the group consisting of:

a substituted or unsubstituted arylene group of 6-60 carbons;

a substituted or unsubstituted heterocyclic arylene group of 2-60 carbons in which at least one hetero-atom selected from the group consisting of N, S, O, P and Si is incorporated in an aromatic ring;

a substituted or unsubstituted arylenevinylene group of 6-60 carbons;

a substituted or unsubstituted arylamine group of 6-60 carbons;

a substituted or unsubstituted carbazole group of 12-60 carbons; and

combinations thereof.

In connection with this, B may have a substituent selected from the group consisting of a linear or branched alkyl or alkoxy group of 1-20 carbons, an aryl group which is unsubstituted or substituted with at least one substituent group selected from the group consisting of linear or branched alkyl and alkoxy groups of 1-20 carbons, a cyano group (—CN), and a silyl group.

More preferably,

When B is a phenylene group or fluorenyl group, among the substituted or unsubstituted arylene group of 6-60 carbons, it may be selected from the group consisting of

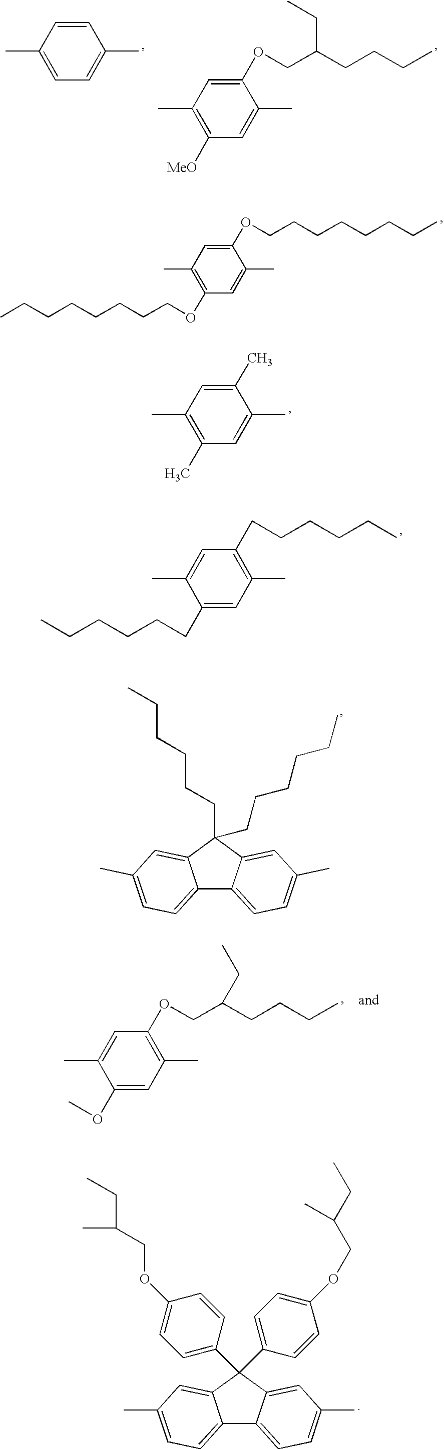

When B is a substituted or unsubstituted heterocyclic arylene group of 2-60 carbons, it may be selected from the group consisting of

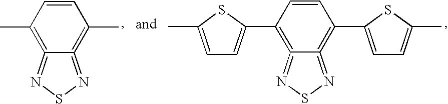

When B is a substituted or unsubstituted arylenevinylene group of 6-60 carbons, it may be selected from the group consisting of

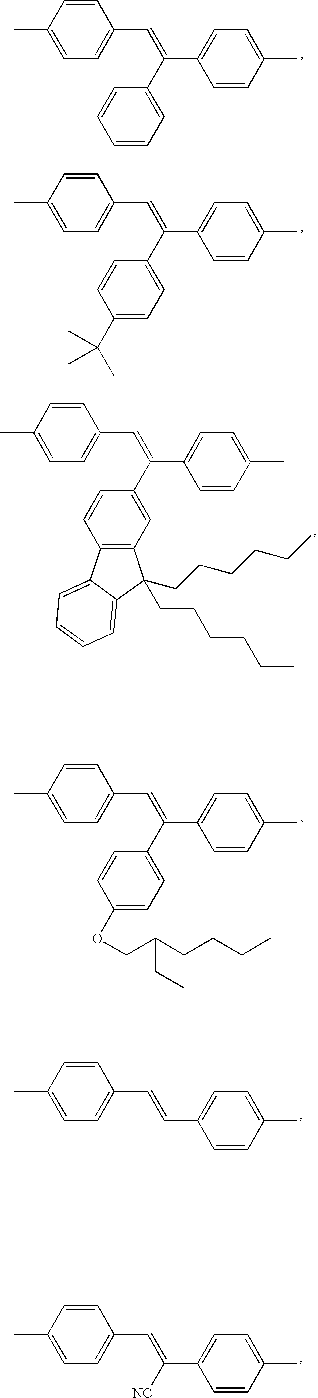

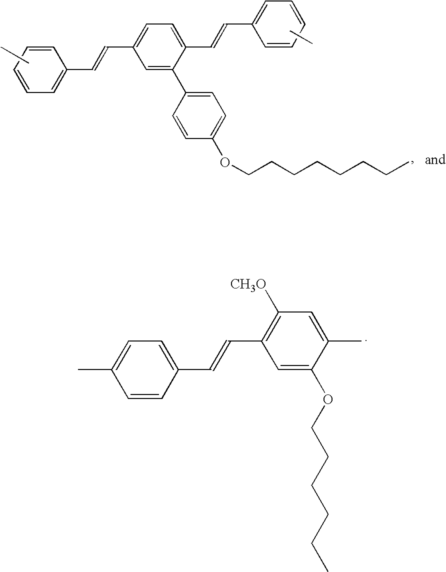

When B is a substituted or unsubstituted arylamine group of 6-60 carbons, it may be selected from the group consisting of

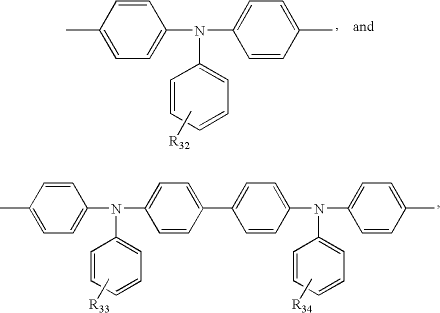

wherein R32, R33, and R34 are the same or different, each being a hydrogen; a linear or branched alkyl or alkoxy group of 1-20 carbons; or an aryl group which is unsubstituted or substituted with at least one substituent group selected from the group consisting of linear or branched alkyl and alkoxy groups of 1-20 carbons,

B being preferably selected from the group consisting of

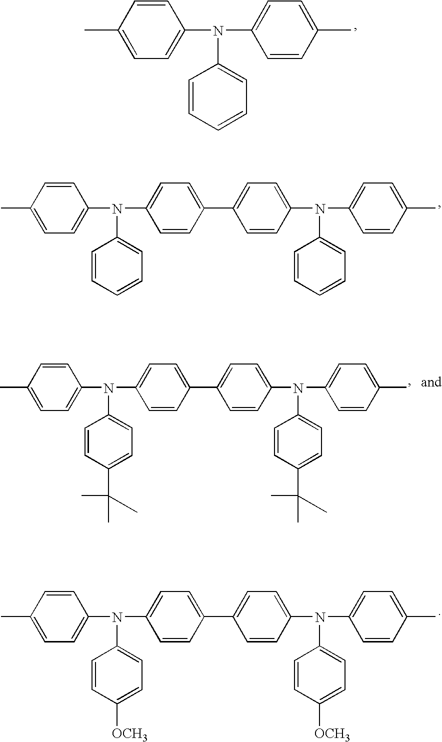

When B is a substituted or unsubstituted carbazole group of 12-60 carbons, it may be

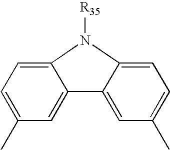

wherein, R35 is a linear or branched alkyl or alkoxy group of 1-20 carbons; or an aryl group which is unsubstituted or substituted with at least one substituent group selected from the group consisting of linear or branched alkyl and alkoxy groups of 1-20 carbons.

One procedure for producing the above-mentioned electroluminescent polymer according to the present invention is as follows. In other words, after monomers are produced using an alkylation reaction, a bromination reaction, a Grignard reaction, and an oxidation reaction, organic electroluminescent polymers are finally produced using a C—C coupling reaction, such as a Yamamoto coupling reaction and a Suzuki coupling reaction. The resulting polymers have a number average molecular weight of 1,500-10,000,000 and a molecular weight distribution of 1-50.

Meanwhile, examples of the monomers used to produce the electroluminescent polymer of the present invention are as follows. The examples are set forth to illustrate, but are not to be construed as the limit of the present invention.

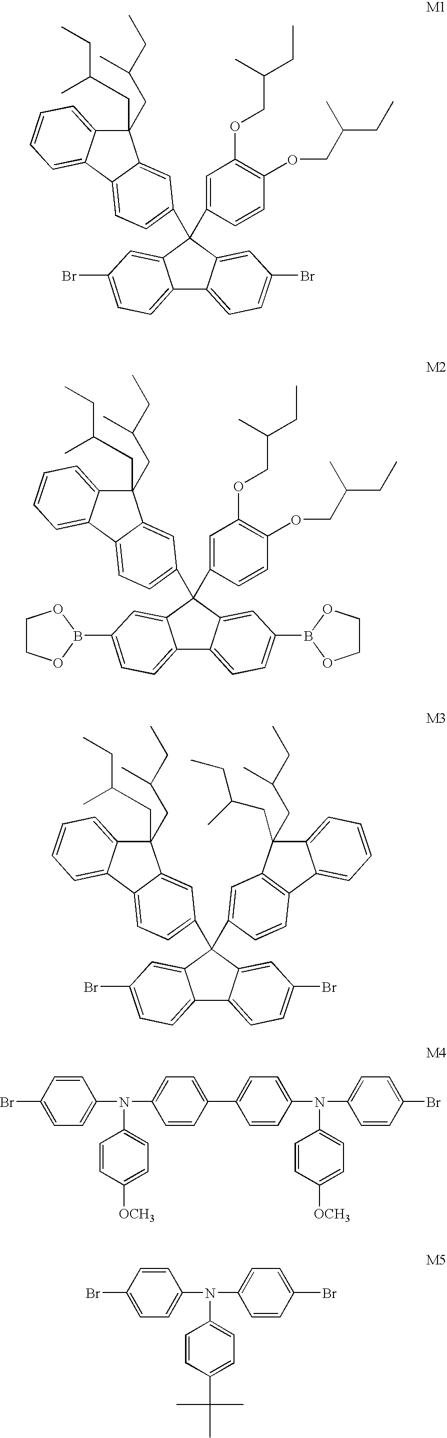

The above-mentioned organic electroluminescent polymer according to the present invention is capable of being used as a host for emitting blue, green, and red rays, which has excellent thermal stability, oxidation stability, and solubility, minimizes interaction between molecules, make energy transfer easy, and maximally suppresses a vibronic mode to assure high light emitting efficiency.

According to the present invention, the organic electroluminescent polymer is used as a material for forming an interlayer, a light-emitting layer, a hole transport layer, an electron transport layer, or a hole-blocking layer interposed between a pair of electrodes in the electroluminescent device.

The electroluminescent device of the present invention may include the most typical components constituting the device, such as an anode/a light-emitting layer/a cathode, and may further include selectively an interlayer, a hole transport layer, and an electron transport layer.

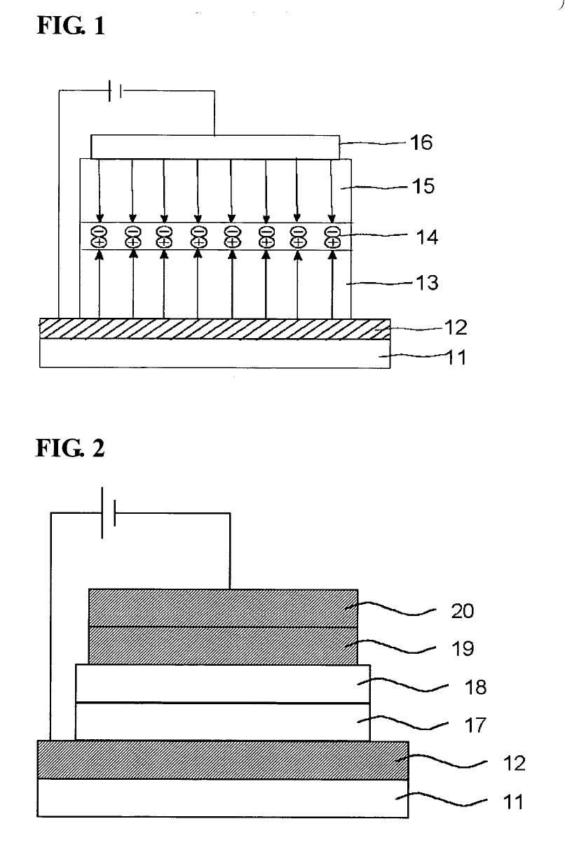

FIG. 1 is a sectional view of a conventional electroluminescent device which includes a substrate/an anode/a hole transport layer/a light-emitting layer/an electron transport layer/a cathode. A description will be given of a method for producing the electroluminescent device using the organic electroluminescent polymer according to the present invention, referring to FIG. 1.

First, a material for an anode 12 is applied on an upper side of a substrate 11.

In connection with this, a typical substrate for the electroluminescent device is used as the substrate 11, and it is preferable to use a glass substrate or transparent plastic substrate having excellent transparency, surface flatness, ease in use, and waterproofness.

Furthermore, the material for the anode 12 may be exemplified by indium tin oxide (ITO), tin oxide (SnO₂), and zinc oxide (ZnO), which are transparent and have excellent conductivity.

Next, the hole transport layer 13 may be formed on an upper side of the anode 11 through vacuum deposition or sputtering, and the light-emitting layer 14 may be formed using a solution coating method, such as spin coating or inkjet printing. As well, the electron transport layer 15 is formed on an upper side of the light-emitting layer 14 before the cathode 16 is formed. In connection with this, the thickness of the light-emitting layer 14 is 5 nm-1 μm, and preferably 10-500 nm, and the hole transport layer and the electron transport layer each is 10-10,000 Å in thickness.

According to the present invention, the electron transport layer 15 may be formed using a typical material for forming the electron transport layer or using the compound shown in Formula 1 through vacuum deposition, sputtering, spin coating, or inkjet printing.

The hole transport layer 13 and the electron transport layer 15 efficiently transport carriers to a luminescent polymer to increase light emitting combination in the luminescent polymer. Examples of materials for forming the hole transport layer 13 and the electron transport layer 15 useful in the present invention are not limited. However, preferable examples of the material for forming the hole transport layer include PEDOT:PSS in which poly(3,4-ethylenedioxy-thiophene) (PEDOT) is doped onto a (poly(styrene sulfonic acid) (PSS) layer, and N,N′-bis(3-methylphenyl)-N,N-diphenyl-[1,1′-biphenyl]-4,4′-diamine (TPD), and preferable examples of the material for forming the electron transport layer include aluminum trihydroxyquinoline (Alq3), PBD(2-(4-biphenylyl)-5-phenyl-1,3,4-oxadiazole) as a 1,3,4-oxadiazole derivative, TPQ(1,3,4-tris[(3-penyl-6-trifluoromethyl)quinoxaline-2-yl]benzene) as a quinoxaline derivative, and a triazole derivative.

Meanwhile, when forming a layer using the organic electroluminescent polymer according to the present invention through the solution-coating method, it may be blended with other fluorene-based polymers and polymers having a conjugated double bond, such as polyphenylenevinylenes and polyparaphenylenes. If necessary, it may be blended with a binder resin. Examples of the binder resin include polyvinylcarbazole, polycarbonate, polyester, polyarylate, polystyrene, an acrylic polymer, a methacrylic polymer, polybutyral, polyvinyl acetal, a diallyl phthalate polymer, a phenol resin, an epoxy resin, a silicon resin, a polysulfonic resin, or a urea resin. The above-mentioned resins may be used alone or in a combination form.

Selectively, the hole blocking layer made of LiF (lithium fluoride) may be additionally formed using vacuum deposition or the like to limit a transport speed of a hole and to increase combination of electrons and holes in the light-emitting layer 14.

Finally, a material for the cathode 16 is applied on an upper side of the electron transport layer 15.

Metal for forming the cathode is exemplified by lithium (Li), magnesium (Mg), calcium (Ca), aluminum (Al), Al:Li, Ba:Li, and Ca:Li, which have a small work function.

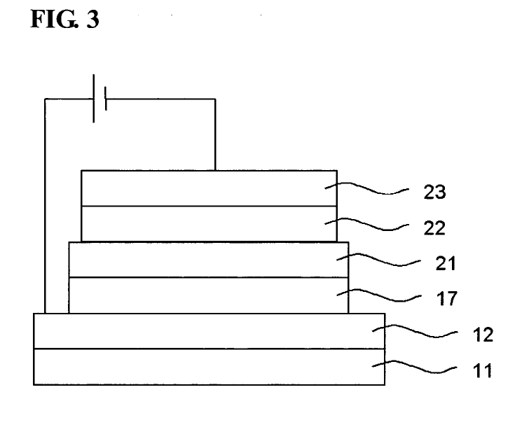

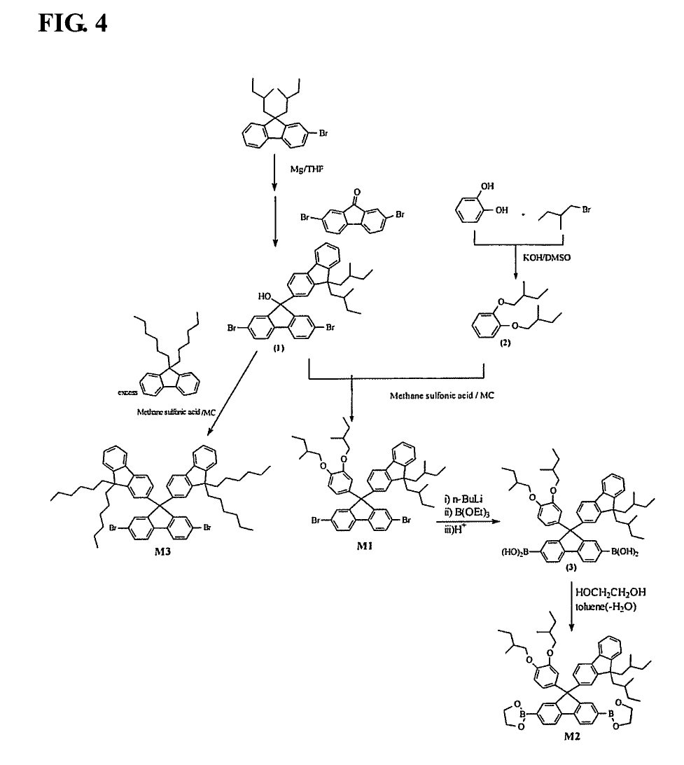

As an example of a structure of an electroluminescence device which is capable of being produced according to the method of the present invention, a structure of an electroluminescence device according to another embodiment of the present invention is shown in FIGS. 2 and 3.

Referring to FIG. 2, the electroluminescent device according to the present embodiment of the invention may include a substrate 11, an anode 12, a hole transport layer 17 (500 Å) made of PEDOT:PSS, a light-emitting layer 18 (100-2000 Å) made of the electroluminescent polymer shown in Formula 1, a hole blocking layer 19 (20 Å) made of LiF, and a cathode layer (700 Å) made of Al.

Referring to FIG. 3, an electroluminescent device according to yet another embodiment of the present invention may include a substrate 11, an anode 12, a hole transport layer 17 (500 Å) made of PEDOT:PSS, a light-emitting layer 21 (100-2000 Å) made of the electroluminescent polymer shown in Formula 1, and a Ca:Al cathode layer made of Ca 22 (500 Å) and Al 23 (1500 Å).

The electroluminescent device according to the present invention may be produced by sequentially layering the anode/the interlayer/the hole transport layer/the light-emitting layer/the electron transport layer/the cathode according to the order as described above, or, reversely, by sequentially layering the cathode/the electron transport layer/the light-emitting layer/the hole transport layer/the interlayer/the anode.

Furthermore, the organic electroluminescent polymer according to the present invention may be used in a polymer organic electroluminescent device, and also be used as a photoconversion material in a photodiode and as a semiconductor material in a polymer TFT (thin-film transistor).

As described above, in the organic electroluminescent polymer according to the present invention, a fluorenyl group as a large substituent is introduced to a 9-position of fluorene used as a main chain thereof so that the substituent has the same structure as the main chain, thus the main chain and the substituent are randomly arranged and an excimer between molecules caused by the substituent is maximally suppressed; thereby aggregation and/or formation of an excimer, which are considered the most serious problems in polyfluorenes, are suppressed. Moreover, energy transfer from the substituent group having a short wavelength to the main chain is possible in a molecule or between molecules. In addition, rotation and vibronic modes are supressed due to the large fluorenyl group substituted at the 9-position of the fluorene group used as the main chain to significantly reduce nonradiative decay, thus excellent thermal stability, photostability, solubility, and film moldability, and high quantum efficiency are assured. Accordingly, the organic electroluminescent polymer and the electroluminescent device using the same according to the present invention are characterized in that chromatic purity and brightness are excellent, efficiency is high, and a glass transition temperature (Tg) is high due to rotation hindrance by the large substituent, thus it is possible to significantly improve lifespan of the device.

A better understanding of the present invention may be obtained through the following examples which are set forth to illustrate, but are not to be construed as the limit of the present invention.

### PREPARATION EXAMPLE 1

### Synthesis of (9-(9,9-di(2-methyl)buylfluoren-2-yl)-2,7-dibromofluorene-9-ol) (1)

3.3 g (137 mmol) of Mg was put into a 500 mL three-neck flask, and 44 g (114 mmol) of 9,9-di(2-methyl)butyl-2-bromofluorene which was melted in 200 mL of THF was then slowly dropped thereonto to produce a Grignard reagent. After the temperature of a reaction vessel was reduced to −40° C. or less, 30 g (91 mmol) of 2,7-dibromofluorene was added thereto in a nitrogen atmosphere, the temperature was slowly increased to normal temperature, and agitation was conducted for 10 hours. Reactants were poured into water, extraction was conducted using diethyl ether, and the solvent was removed using a rotary evaporator. Separation was conducted using a column chromatography method to produce 43 g (67 mmol, 73%) of 9-(9,9-di(2-methyl)butylfluoren-2-yl)-2,7 -dibromofluorene-9-ol (1).

### PREPARATION EXAMPLE 2

### Synthesis of 1,2-di(2-methyl)butyloxybenzene (2)

20 g (91 mmol) of catechol compound and 107 g (436 mmol) of 2-methylbutyl p-toluenesulfonate were dissolved in 200 mL of DMSO in a 500 mL round flask, 53 g equivalents (473 mmol) of potassium tertiary butoxide (t-BuOK) was slowly added thereto, and a reaction was conducted at 70° C. for 12 hours. Reactants were poured into 500 mL of water, extraction was conducted using methylene chloride, the solvent was removed using a rotary evaporator, and separation was conducted through a column chromatography method using a mixed solvent of hexane and ethyl acetate to produce 37 g (148 mmol, 81%) of 1,2-di(2-methyl)butyloxybenzene (2).

### PREPARATION EXAMPLE 3

### Synthesis of a Monomer M1

50 g (78 mmol) of compound (1) produced in preparation example 1 and 23.3 g (93 mmol) of compound (2) produced in preparation example 2 were dissolved in 1000 mL of dichloromethane in a 2 L round flask, the temperature was reduced to 0° C., a solution in which 7.5 g (78 mmol) of methane sulfonic acid was dissolved in 100 mL of dichloromethane while agitating was slowly added thereto, and agitation was conducted for 2 hours. Reactants were poured into water, extraction was conducted using diethyl ether, and the solvent was removed using a rotary evaporator. Separation was conducted using a column chromatography method to produce 67 g (65 mmol, 84%) of 2,7-dibromo-9-(9,9-di(2-methylbutyl)fluoren-2-yl)-9-(3,4-di(2-methyl)butyloxyphenyl)fluorene (M1).

### PREPARATION EXAMPLE 4

### Synthesis of a 9-(9,9-di(2-metylbutyl)fluoren-2-yl)-9-(3,4-di(2-methyl)butyloxyphenyl)fluorine-2,7-diboronic acid (3)

10 g of compound (2) was put into a 250 mL round flask, dissolved in 60 mL of THF, and cooled to −70° C. 2 equivalents of 2.5M n-butyl lithium were slowly added thereto, a reaction was conducted at a low temperature of −70 to −40° C. for 2 hours, 4 equivalents of triethyl borate were added thereto at the same temperature, and the reactants were left for 12 hours. The reactants were poured into a 3N HCl aqueous solution, agitated for 4 hours, and extracted using diethyl ether. After the solvent was removed using a rotary evaporator, the solidified substance was repeatedly washed with toluene and dried to produce 7 g (76%) of 9,9-di(9,9-dihexylfluoren-2-yl)fluorene-2,7-diboronic acid (3).

### PREPARATION EXAMPLE 5

### Synthesis of a Monomer M2

After 7 g of compound (3) produced in preparation example 4, 3 equivalents of ethylene glycol, and 50 mL of anhydrous toluene were put into a 100 mL round flask, a deanstark apparatus was installed and a reflux was conducted for 24 hours to remove water. Subsequently, recrystallization was conducted using toluene to produce 6.5 g (87%) of 9-(9,9-di(2-methylbutyl)fluoren-2-yl)-9-(3,4-di(2-methyl)butyloxyphenyl)fluorine-2,7-bisboronic glycol ester (M2).

### PREPARATION EXAMPLE 6

### Synthesis of a Monomer M3

50 g of compound (1) and 200 g of 9,9-dihexylfluorene were dissolved in 1000 mL of dichloromethane in a 2 L round flask, the temperature was reduced to 0° C., a solution in which 10 mL of methane sulfonic acid was dissolved in 100 mL of dichloromethane while agitating was slowly added thereto, and agitation was conducted for 2 hours. Reactants were poured into water, extraction was conducted using diethyl ether, and the solvent was removed using a rotary evaporator. Separation was conducted using a column chromatography method to produce 60 g (58%) of 9,9-di(9,9-dihexylfluoren-2-yl)-2,7-dibromofluorene (M3).

### PREPARATION EXAMPLE 7

### Synthesis of a Monomer M4

This was produced through a synthetic procedure developed by Buchwald and Hartiwig.

### PREPARATION EXAMPLE 8

### Synthesis of a Monomer M5

This was produced through a synthetic procedure developed by Buchwald and Hartiwig.

### EXAMPLES 1-11

### Synthesis of Electroluminescent Polymer

Copolymers were produced through a Yamamoto coupling reaction (reference: Yamamoto et al., Macromolecules, Vol. 25, 1992, p. 1214-1223) and a Suzuki coupling reaction (reference: Chemical Reviews, Vol. 95, 1995, p. 2457-2483) which were known as a carbon-carbon coupling reaction using the monomers M1, M2, M3, M4, and M5 produced according to procedures of preparation example 1 to 8. Their compositions, polymerization methods, and measured molecular weights are described in the following Table 1.

TABLE 1

| | Synthesis | M1 | M2 | M3 | M4 | M5 | Molecular | Molecular weight | |
|---|---|---|---|---|---|---|---|---|---|
| Example | method | (mmol) | (mmol) | (mmol) | (mmol) | (mmol) | Weight (Mw) | (Mn) | PDI |
| 1 | Y | 0.425 | | 0.182 | 0.046 | | 240000 | 6300 | 3.8 |
| 2 | Y | 0.401 | | 0.172 | 0.086 | | 220000 | 6000 | 3.7 |
| 3 | Y | 0.178 | | 0.415 | 0.045 | | 180000 | 5300 | 3.4 |
| 4 | Y | 0.169 | | 0.393 | 0.084 | | 160000 | 6700 | 2.4 |
| 5 | Y | 1.436 | | 0.359 | 0.268 | | 190000 | 7000 | 2.7 |
| 6 | Y | 1.250 | | 0.536 | 0.267 | | 170000 | 5300 | 3.2 |
| 7 | Y | 0.481 | | 0.120 | 0.090 | | 180000 | 6400 | 2.8 |
| 8 | Y | 0.493 | | 0.123 | 0.069 | | 180000 | 6700 | 2.7 |
| 9 | Y | 0.828 | | 0.355 | 0.109 | 0.068 | 120000 | 5000 | 2.4 |
| 10 | Y | 0.329 | | 0.263 | 0.033 | 0.033 | 140000 | 4500 | 3.1 |
| 11 | S | 0.120 | 0.346 | 0.136 | 0.090 | | 800000 | 296000 | 2.7 |

Y: Polymerization using the Yamamoto coupling reaction
S: Polymerization using the Suzuki coupling reaction

### EXAMPLES 12-22

### Production of Electroluminescent Device

After an ITO (indium tin oxide) electrode was formed on a glass substrate, polymers for the electroluminescent device were applied on an upper side of the ITO electrode using spin coating as shown in the following Table 2 to form a light-emitting layer having a thickness of 400-1500 Å. Al:Li were vacuum deposited on an upper side of the light-emitting layer to form an aluminum.lithium electrode having a thickness of 100-1200 Å; thereby the electroluminescent device was produced. Light emitting properties were measured, and are descried in the following Table 2.

TABLE 2

| | | Actuation | Maximum | Color |
|---|---|---|---|---|
| | light-emitting | initiating | efficiency | coordinate |
| Example | layer | voltage (V) | (cd/A) | (x, y) |
| 12 | Example 1 | 3.5 | 2.57 | (0.149, 0.130) |
| 13 | Example 2 | 3.0 | 3.04 | (0.147, 0.120) |
| 14 | Example 3 | 3.0 | 2.89 | (0.148, 0.120) |
| 15 | Example 4 | 3.0 | 2.12 | (0.147, 0.107) |
| 16 | Example 5 | 3.0 | 3.92 | (0.149, 0.158) |
| 17 | Example 6 | 3.0 | 2.53 | (0.152, 0.158) |
| 18 | Example 7 | 3.0 | 2.61 | (0.149, 0.147) |
| 19 | Example 8 | 3.0 | 2.42 | (0.146, 0.111) |
| 20 | Example 9 | 3.5 | 3.08 | (0.148, 0.128) |
| 21 | Example 10 | 3.0 | 2.88 | (0.145, 0.109) |
| 22 | Example 11 | 4.0 | 3.86 | (0.149, 0.147) |

The electroluminescent polymers of examples 1 to 11 were produced using M4 and M5 as amine-based monomers to improve hole transportation and injection properties of basic structures of M1, M2 and M3. Meanwhile, the electroluminescent devices which were produced using them had actuation initiating voltage of 3-4 V and high light emitting efficiency of 2.12-3.98 cd/A as shown in Table 2. Furthermore, even though TPD (Triphenyl Diamine)-based amine was used, excellent color purity was assured at a blue light emitting region in terms of light emitting property, thus it could be confirmed that the electroluminescent polymer which is developed according to the present invention is useful as the light-emitting layer for the electroluminescent device.

As described above, an electroluminescent polymer according to the present invention is advantageous in that thermal stability is excellent, light emitting efficiency is high, solubility is excellent, interaction between molecules is minimized, and the disadvantages of conventional polyfluorenes are apparently avoided, thus excellent light emitting properties are assured as a host material for blue, green, and red colors of an electroluminescent device.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An electroluminescent polymer having a 9-fluoren-2-yl-2,7-fluorenyl unit represented by Formula 1 below, in which a substituted fluorenyl group is introduced at a 9-position of fluorene: 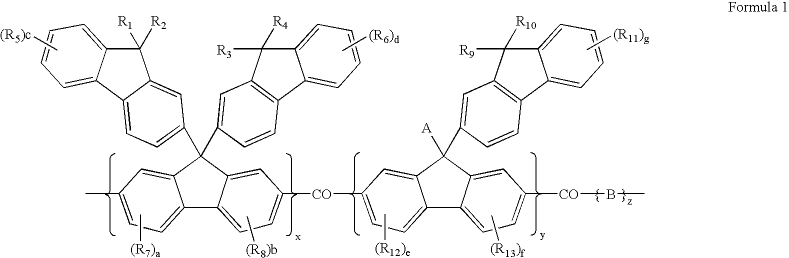
wherein R1, R2, R3, R4, R9, and R10 are each independently a linear or branched alkyl group of 1-20 carbons; an aryl group which is unsubstituted or substituted with at least one substituent group selected from the group consisting of linear or branched alkyl and alkoxy groups of 1-20 carbons; a linear or branched alkyl group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;
R5, R6, R7, R8, R11, R12, and R13 are each independently a hydrogen; a linear or branched alkyl or alkoxy group of 1-20 carbons; an aryl group which is unsubstituted or substituted with at least one substituent group selected from the group consisting of linear or branched alkyl and alkoxy groups of 1-20 carbons; a linear or branched alkyl or alkoxy group of 1-20 carbons having at least one hetero-atom selected from the group consisting of F, S, N, O, P and Si; an aryl group which is substituted with at least one substituent group selected from the group consisting of linear or branched alkyl and alkoxy groups of 1-20 carbons having at least one hetero-atom selected from the group consisting of F, S, N, O, P and Si; an aryl group having a heterocyclic moiety of 2-24 carbons which is unsubstituted or substituted with at least one substituent group selected from the group consisting of linear or branched alkyl and alkoxy groups of 1-20 carbons; an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si; a substituted or unsubstituted trialkylsilyl group of 3-40 carbons; a substituted or unsubstituted arylsilyl group of 3-40 carbons; a substituted or unsubstituted carbazole group of 12-60 carbons; a substituted or unsubstituted phenothiazine group of 6-60 carbons; or a substituted or unsubstituted arylamine group of 6-60 carbons;
a, b, c, d, e, f, and g are each independently an integer from 1 to 3;
A is an aryl group which is unsubstituted or substituted with at least one substituent group selected from the group consisting of linear or branched alkyl and alkoxy groups of 1-20 carbons; an aryl group which is substituted with at least one substituent group selected from the group consisting of linear or branched alkyl and alkoxy groups of 1-20 carbons having at least one hetero-atom selected from the group consisting of F, S, N, O, P and Si;
an aryl group having a heterocyclic moiety of 2-24 carbons which is unsubstituted or substituted with at least one substituent group selected from the group consisting of linear or branched alkyl and alkoxy groups of 1-20 carbons; or an aryl group having a heterocyclic moiety of 2-24 carbons which is substituted with at least one substituent group selected from the group consisting of linear or branched alkyl and alkoxy groups of 1-20 carbons having at least one hetero-atom selected from the group consisting of F, S, N, O, P and Si;
B is selected from the group consisting of a substituted or unsubstituted aromatic moiety of 6-60 carbons, a substituted or unsubstituted heteroaromatic moiety of 2-60 carbons, and combinations thereof; and
x is an integer from 1-100,000, y is an integer from 1-100,000, and z is an integer from 0-100,000.

2. The electroluminescent polymer as set forth in claim 1, wherein said R1, R2, R3, R4, R9, and R10 are each independently selected from the group consisting of

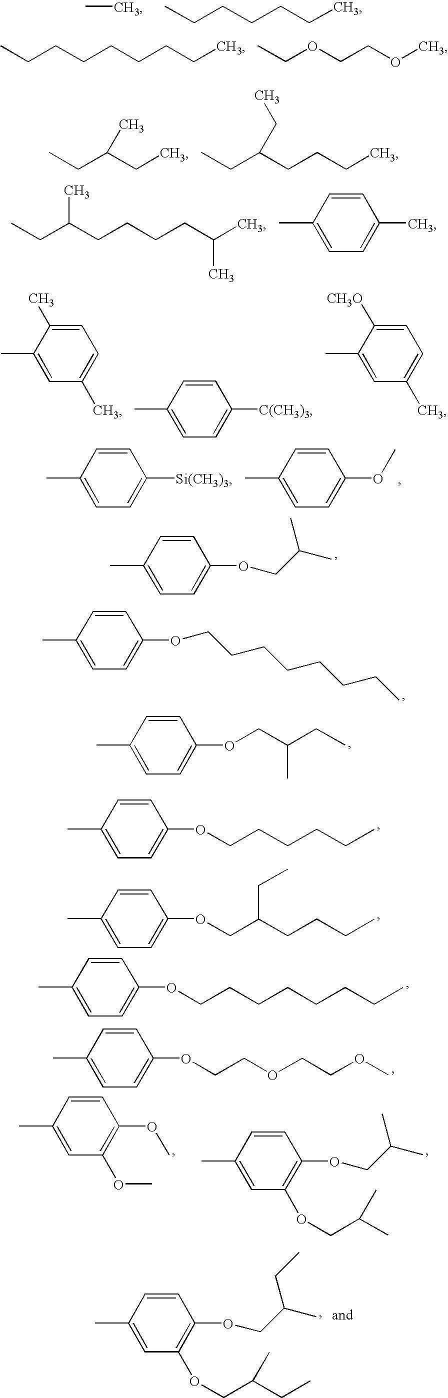

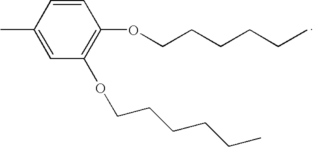

3. The electroluminescent polymer as set forth in claim 1, wherein said R5, R6, and R11 are each independently selected from the group consisting of
hydrogen, 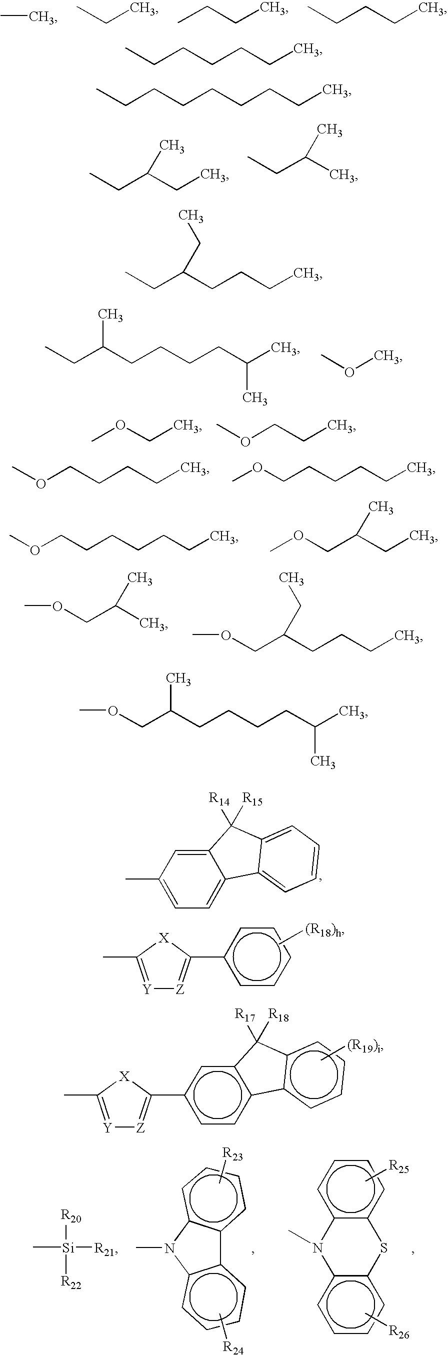 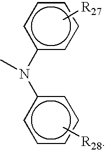
wherein R14 and R15 are each independently a linear or branched alkyl group of 1-20 carbons;
R16 is a hydrogen, a linear or branched alkyl, or an alkoxy or trialkylsilyl group of 1-20 carbons;
R17 and R18 are each independently a linear or branched alkyl group of 1-20 carbons, R19 is a hydrogen, a linear or branched alkyl, or an alkoxy or trialkylsilyl group of 1-20 carbons, X is O or S, Y and Z are each N, and h and i are each independently an integer from 1 to 3;
R20, R21, and R22 are each independently a linear or branched alkyl or alkoxy group of 1-20 carbons; or an aryl group which is unsubstituted or substituted with at least one substituent group selected from the group consisting of linear or branched alkyl and alkoxy groups of 1-20 carbons; and
R23, R24, R25, R26, R27, and R28 are each independently a hydrogen; a linear or branched alkyl or alkoxy group of 1-20 carbons; or an aryl group which is unsubstituted or substituted with at least one substituent group selected from the group consisting of linear or branched alkyl and alkoxy groups of 1-20 carbons.

4. The electroluminescent polymer as set forth in claim 1, wherein said R7, R8, R12, and R13 are each independently selected from the group consisting of a hydrogen,

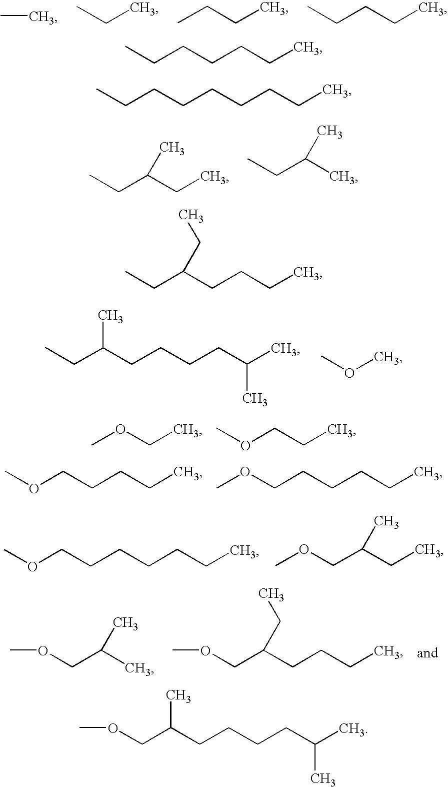

5. The electroluminescent polymer as set forth in claim 1, wherein said A is 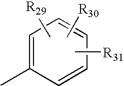
wherein R29, R30, and R31 are each independently a hydrogen; a linear or branched alkyl or alkoxy group of 1-20 carbons; or a linear or branched alkyl or alkoxy group of 1-20 carbons having at least one hetero-atom selected from the group consisting of F, S, N, O, P and Si.

6. The electroluminescent polymer as set forth in claim 1, wherein said B is selected from the group consisting of
(i) a substituted or unsubstituted arylene group of 6-60 carbons;
(ii) a substituted or unsubstituted heterocyclic arylene group of 2-60 carbons in which at least one hetero-atom selected from the group consisting of N, S, O, P and Si is incorporated in an aromatic ring;
(iii) a substituted or unsubstituted arylenevinylene group of 6-60 carbons;
(iv) a substituted or unsubstituted arylamine group of 6-60 carbons;
(v) a substituted or unsubstituted carbazole group of 12-60 carbons; and
(vi) combinations thereof,
in which B has a substituent selected from the group consisting of a linear or branched alkyl or alkoxy group of 1-20 carbons, an aryl group which is unsubstituted or substituted with at least one substituent group selected from the group consisting of linear or branched alkyl and alkoxy groups of 1-20 carbons, a cyano group (—CN), and a silyl group.

7. The electroluminescent polymer as set forth in claim 1, wherein a ratio of x+y:z is 50-100: 0-50.

8. The electroluminescent polymer as set forth in claim 1, wherein the electroluminescent polymer is a random copolymer or a syndiotactic copolymer.

9. The electroluminescent polymer as set forth in claim 1, wherein the electroluminescent polymer has a number average molecular weight of 1,500-10,000,000 and a molecular weight distribution of 1-50.

10. An electroluminescent device having at least one layer comprising the electroluminescent polymer according to claim 1 between an anode and a cathode,
wherein the layer is an interlayer, a hole transport layer, a light emitting layer, an electron transport layer, or a hole blocking layer.

11. The electroluminescent device as set forth in claim 10, wherein the electroluminescent device comprises a light emitting layer interposed between an anode and a cathode.

12. The electroluminescent device as set forth in claim 11, further comprising an interlayer interposed between the anode and the light emitting layer.

13. The electroluminescent device as set forth in claim 12, further comprising a hole transport layer interposed between the interlayer and the light emitting layer.

14. The electroluminescent device as set forth in claim 13, further comprising an electron transport layer interposed between the light emitting layer and the cathode.
